(19) United States
(12) Patent Application Publication
(10) Pub. No.: US 2014/0241063 A1
(43) Pub. Date: Aug. 28, 2014

(54) SEMICONDUCTOR MEMORY DEVICE

(71) Applicant: KABUSHIKI KAISHA TOSHIBA, Tokyo (JP)

(72) Inventor: Takashi MAEDA, Kanagawa (JP)

(73) Assignee: KABUSHIKI KAISHA TOSHIBA, Tokyo (JP)

(21) Appl. No.: 14/016,194

(22) Filed: Sep. 2, 2013

(30) Foreign Application Priority Data
Feb. 28, 2013 (JP) 2013-039020

(51) Int. Cl. G11C 16/30

(52) U.S. Cl. CPC G11C 16/30
USPC 365/185.17

(57) ABSTRACT

A semiconductor memory device comprises a memory string including first and second selection transistors, and first and second groups of memory cell transistors connected in series between the first and second selection transistors; a bit line and a source line respectively connected to the first and second selection transistors; first word lines respectively connected to gates of the memory cell transistors in the first group; second word lines respectively connected to gates of the memory cell transistors in the second group; first transfer transistors respectively connected to the first word lines; second transfer transistors respectively connected to the second word lines; and a control unit configured to apply a first control voltage to gates of the first transfer transistors and a second control voltage lower than the first control voltage to gates of the second transfer transistors when data is being written to memory cell transistors in the first group.

### CROSS-REFERENCE TO RELATED APPLICATION

This application is based upon and claims the benefit of priority from Japanese Patent Application No. 2013-039020, filed Feb. 28, 2013, the entire contents of which are incorporated herein by reference.

### FIELD

Embodiments described herein relate generally to a semiconductor memory device.

### BACKGROUND

NAND type flash memory in which memory cells are arranged three-dimensionally is known in the art.

### DESCRIPTION OF THE DRAWINGS

FIG. 1 is a block diagram of the semiconductor memory device according to a first embodiment.

FIG. 2 is a circuit diagram of the memory cell array.

FIG. 3 is a perspective view of the memory cell array.

FIG. 4 is a cross-section diagram of the memory cell array.

FIG. 5 is a circuit diagram of the transfer gate on the source line side and the block decoder.

FIG. 6 is a circuit diagram of the transfer gate on the bit line side and the block decoder.

FIG. 7 is a circuit diagram illustrating the load capacitance of the memory cell array.

FIG. 8 is a cross-section diagram illustrating the load capacitances of the memory cell array.

FIG. 9 is a view illustrating the voltage relationships in a write operation according to the first embodiment.

FIG. 10 is a timing chart of the write operation according to the first embodiment.

FIG. 11 is a view illustrating the voltage relationships in a write operation according to a second embodiment.

FIG. 12 is a timing chart of the write operation according to the second embodiment.

FIG. 13 is a view illustrating the voltage relationships in a write operation according to a third embodiment.

FIG. 14 is a timing chart of the write operation according to the third embodiment.

### DETAILED DESCRIPTION

Embodiment provide a semiconductor memory device capable of reducing power consumption during writing.

In general, a semiconductor memory device according to one embodiment comprises: a memory string including first and second selection transistors, a back gate transistor, a first group of memory cell transistors connected in series between the first selection transistor and the back gate transistor, and a second group of memory cell transistors connected in series between the second selection transistor and the back gate transistor; a bit line connected to the first selection transistor; a source line connected to the second selection transistor; a plurality of first word lines respectively connected to gates of the memory cell transistors in the first group; a plurality of second word lines respectively connected to gates of the memory cell transistors in the second group; a back gate line connected to a gate of the back gate transistor; a plurality of first transfer transistors respectively connected to the first word lines; a plurality of second transfer transistors respectively connected to the second word lines; and a control unit configured to apply a first control voltage to gates of the first transfer transistors and a second control voltage lower than the first control voltage to gates of the second transfer transistors when data is being written to memory cell transistors in the first group.

Hereinafter, embodiments are described with reference to the drawings. Hereinafter, several embodiments are described which provide examples of devices and methods which embody the technical ideas of the present disclosure. However, the technical ideas of the present disclosure are not limited to the shapes, structures, arrangements and the like of components of the examples given. Furthermore, in the description given below, the same reference numerals are assigned to elements which have the same functions and configurations, and duplicate explanation will only be provided as necessary.

### First Embodiment

### 1. Overall Configuration of Semiconductor Memory Device 1

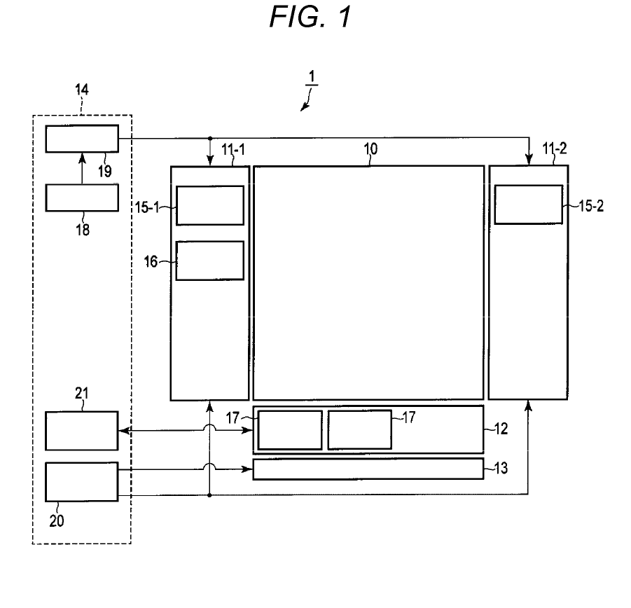

FIG. 1 is a block diagram of the semiconductor memory device 1 according to a first embodiment. Each of the functional blocks does not need to be distinguished from one another as shown in FIG. 1, or in any of the other diagrams. For example, some of the functions may also be executed by a different function block from the function block exemplified in the description below. Furthermore, the exemplified functional blocks may also be divided into more specific functional sub-blocks.

The semiconductor memory device 1 is configured from a stacked NAND type flash memory in which a plurality of memory cells is arranged three-dimensionally. The semiconductor memory device 1 includes a memory cell array 10, row decoders 11 (11-1, 11-2), a sense circuit 12, a column decoder 13 and a control circuit 14.

The memory cell array 10 includes a plurality of blocks (memory blocks). Each of the blocks includes a plurality of NAND strings in which nonvolatile memory cells are connected in series. The word lines are connected to the gates of the memory cells within the NAND string. The bit line is connected to one end of the NAND string, and the source line is connected to the other end. The memory cell array 10 is described in detail later.

The row decoders 11-1 and 11-2 select the row direction of the memory cell array 10. During writing and reading of data, the row decoders 11-1 and 11-2 select one of the word lines and transfer the necessary voltages to the selected word lines and the unselected word lines. The row decoders 11-1 and 11-2 are respectively arranged on both sides in the row direction of the memory cell array 10. For example, the row decoder 11-1 controls half of the word lines connected to the NAND string and the row decoder 11-2 controls the remaining half.

The row decoders 11-1 and 11-2 respectively include transfer gates 15-1 and 15-2. In addition, at least one of the row decoders 11-1 and 11-2 includes a cell source line control circuit 16. The transfer gates 15-1 and 15-2 are connected to the word line in series and apply various voltages, including high voltages, to the word line. The cell source line control circuit 16 controls the voltage of the source line.

The sense circuit 12 reads out data from the memory cell array 10 and temporarily holds the read data. In addition, the sense circuit 12 receives write data from the outside of the semiconductor memory device 1 and writes the received write data to the selected memory cell. The sense circuit 12 includes a plurality of sense modules 17 provided to correspond to the bit lines. During reading of data, each of the sense modules 17 senses and amplifies the data read out to the bit line. In addition, during writing of data, the write data is transferred to the bit line.

The column decoder 13 selects the column direction of the memory cell array 10. Specifically, during transfer of write data and read data, the column decoder 13 selects one of the sense modules 17.

The control circuit 14 controls the operations of the semiconductor memory device 1 in a unified manner. The control circuit 14 receives commands, which instruct the reading, the writing, the erasing and the like of the data, from a command register (not shown). Furthermore, the control circuit 14 controls the read operations, the write operations, the erasing operations and the like according to a predetermined sequence. The control circuit 14 includes a voltage generation circuit 18, a driver circuit 19, an address decoder 20 and an input-output circuit 21.

For example, the voltage generation circuit 18 generates the voltages necessary for writing, reading and erasing of data in response to the commands of a state machine (not shown). The driver circuit 19 supplies the necessary voltages, of the plurality of voltages supplied from the voltage generation circuit 18, to the row decoders 11-1 and 11-2. Furthermore, the voltages supplied from the driver circuit 19 are applied to the word line by the row decoders 11-1 and 11-2.

The address decoder 20 receives the address from an address buffer (not shown). Then, the address decoder 20 transmits the row address to the row decoders 11-1 and 11-2 and the column address to the column decoder 13.

### 1-1. Configuration of Memory Cell Array 10

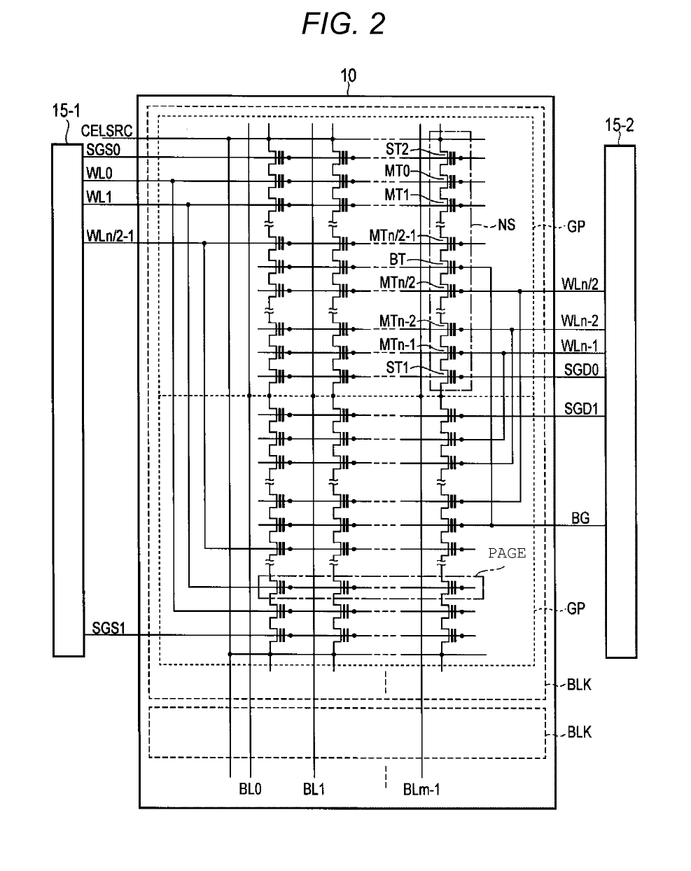

Next, the configuration of the memory cell array 10 is described. FIG. 2 is a circuit diagram of the memory cell array 10. The memory cell array 10 includes a plurality of blocks BLK. Each of the blocks BLK includes a plurality of string groups GP. Each of the string groups GP includes m (where m is a natural number) NAND strings NS.

Each of the NAND strings NS includes, for example, n (where n is a natural number of 2 or higher) memory cell transistors MT, selection transistors ST1 and ST2 and a back gate transistor BT. The memory cell transistor MT includes a stacked gate containing a control gate and a charge storage layer, and maintains data in a non-volatile manner. The number of the memory cell transistors MT contained in one NAND string NS is, for example, 16, 32, 64, 128 or the like, and there is no limitation on the number. The back gate transistor BT includes, in the same manner as the memory cell transistor MT, a stacked gate containing a control gate and a charge storage layer. The back gate transistor BT is not for holding data, and functions, for example, as a current path during writing, reading and erasing of data.

The memory cell transistor MT and the back gate transistor BT are arranged such that the current path thereof is connected in series between the selection transistors ST1 and ST2. The back gate transistor BT is arranged in the center of n memory cell transistors MT. The current path of the memory cell transistor MTn−1 at an end side of the series connection is connected to one end of the current path of the selection transistor ST1, and the current path of the memory cell transistor MT0 at the other end side is connected to one end of the current path of the selection transistor ST2. In other words, the memory cell transistors MT0 to MTn/2−1 are connected in series between the selection transistor ST2 and the back gate transistor BT, and the memory cell transistors MTn/2 to MTn−1 are connected in series between the back gate transistor BT and the selection transistor ST1.

The gate of the selection transistor ST1 contained in the string group GP is connected in common with the selection gate line SGD, and the gate of the selection transistor ST2 contained in the string group GP is connected in common with the selection gate line SGS. The control gate of the memory cell transistors MT0 to MTn−1 contained in the same block BLK are connected in common with the word lines WL0 to WLn−1, respectively, and the control gate of the back gate transistor BT is connected in common with the back gate line BG.

In other words, the word lines WL0 to WLn−1 and the back gate lines BG are connected in common between a plurality of the string groups GP within the same block BLK, whereas, even while being in the same block BLK, the selection gate lines SGD and SGS are isolated for each string group GP.

The selection gate line SGS and the word lines WL0 to WLn/2−1 are connected to the transfer gate 15-1. The selection gate line SGD, the word lines WLn/2 to WLn−1 and the back gate line BG are connected to the transfer gate 15-2.

The other end of the current path of the selection transistor ST1 of, among the NAND strings NS arranged in a matrix within the memory cell array 10, the NAND string NS in the same column is connected in common with one of the bit lines BL (BL0 to BLm−1). In other words, the bit line BL is connected in common with the NAND string NS between the plurality of blocks BLK. In addition, the other end of the current path of the selection transistor ST2 is connected in common with the cell source line (the source line) CELSRC. For example, the source line CELSRC is connected in common with the NAND string NS between the plurality of blocks BLK.

The data of the memory cell transistors MT contained in the same block BLK is erased as a group. In contrast, reading and writing of the data is performed as a group for each of the plurality of memory cell transistors MT connected in common with one of the word lines WL in one of the string groups GP of one of the blocks BLK. The unit of reading and writing is referred to as a “page”.

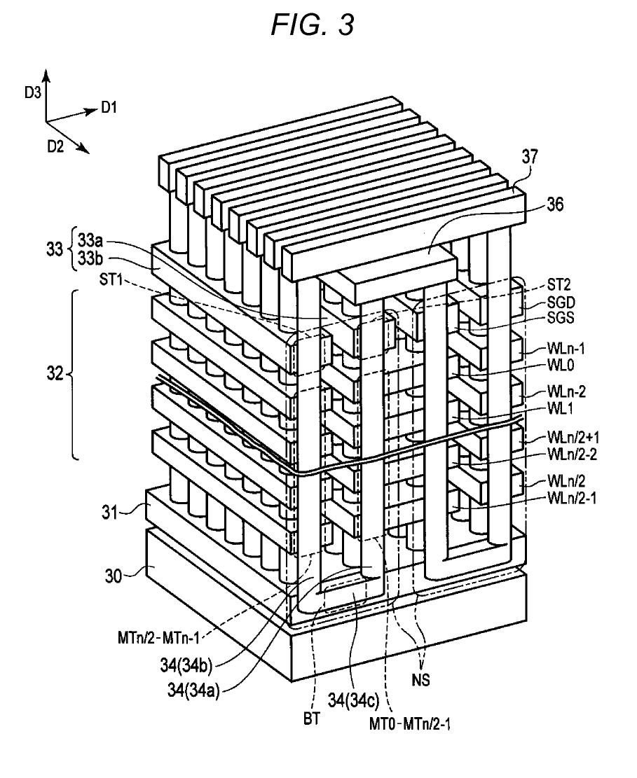

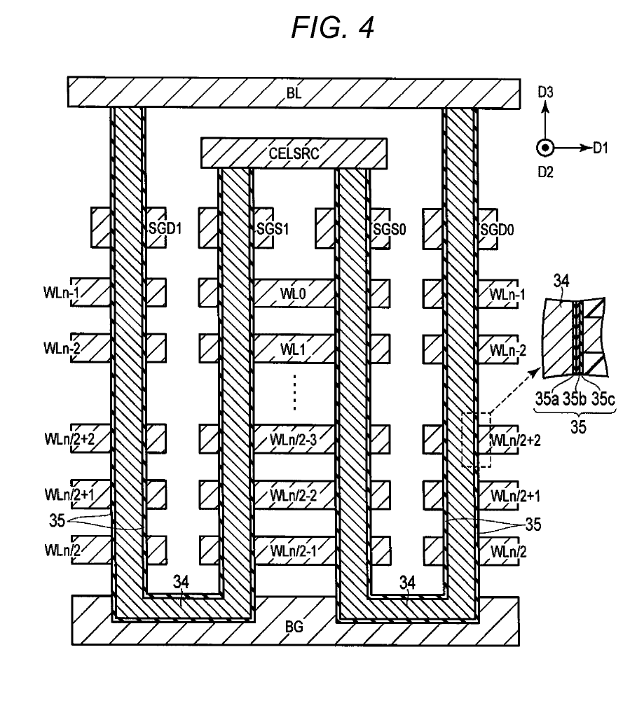

Next, the three-dimensional stacked structure of the memory cell array 10 is described. FIG. 3 is a perspective view of the memory cell array 10. FIG. 4 is a cross-section diagram of the memory cell array 10.

The memory cell array 10 is provided on a semiconductor substrate 30. A back gate conductive layer 31, a plurality of word line conductive layers 32 and selection gate conductive layers 33 (33a and 33b) are respectively stacked onto the semiconductor substrate 30 via insulating films.

The back gate conductive layer 31 is formed so as to spread two-dimensionally in a first direction D1 and a second direction D2 parallel to the semiconductor substrate 30. The first direction D1 and the second direction D2 are orthogonal to a third direction D3 along which the memory cells are stacked. The back gate conductive layer 31 is segmented for each of the blocks BLK. The back gate conductive layer 31, for example, is configured from polycrystalline silicon. The back gate conductive layer 31 functions as the back gate line BG.

The plurality of word line conductive layers 32 are stacked with an interlayer insulating film interposed therebetween (not shown). The plurality of word line conductive layers 32 are formed in a striped pattern extending in the second direction D2 at a predetermined pitch in the first direction D1. The word line conductive layer 32, for example, is configured from polycrystalline silicon. The plurality of word line conductive layers 32 function as the control gates of the memory cell transistors MT0 to MTn−1 (the word lines WL0 to WLn−1).

The selection gate conductive layers 33a and 33b are formed in a striped pattern extending in the second direction D2 so as to have a predetermined pitch in the first direction D1. Pairs of the selection gate conductive layers 33a and pairs of the selection gate conductive layers 33b are arranged alternately in the first direction D1. The selection gate conductive layers 33a and 33b, for example, are configured from polycrystalline silicon. The selection gate conductive layer 33a functions as the gate of the selection transistor ST2 (the selection gate line SGS), and the selection gate conductive layer 33b functions as the gate of the selection transistor ST1 (the selection gate line SGD).

Furthermore, as shown in FIG. 3 and FIG. 4, in the present embodiment, for example, in two NAND strings NS where the selection gate lines SGS neighbor one another, the word lines WL0 to WLn/2−1 are respectively configured using a common conductive layer.

The semiconductor layer 34 is formed in a U-shape when viewed from the second direction D2. In other words, the semiconductor layer 34 includes a pair of semiconductor pillars 34a and 34b which extend in a direction perpendicular to the surface of the semiconductor substrate 30, and a semiconductor layer 34c which links the lower ends of the pair of the semiconductor pillars 34a and 34b. The semiconductor pillar 34a is formed so as to pass through the selection gate conductive layer 33a and the plurality of word line conductive layers 32. The semiconductor pillar 34b is formed so as to pass through the selection gate conductive layer 33b and the plurality of word line conductive layers 32. The semiconductor pillars 34a and 34b are connected by the semiconductor layer 34c which extends in the first direction D1 within the back gate conductive layer 31. The semiconductor layer 34 functions as the body (the back gate of each of the transistors) of the NAND string NS. The semiconductor layer 34, for example, is configured from polycrystalline silicon.

The memory cell transistor MT, the back gate transistor BT and the selection transistors ST1 and ST2 each have an insulating film 35. The insulating film 35 includes a tunnel insulating layer 35a, a charge storage layer 35b and a block insulating layer 35c. The tunnel insulating layer 35a is formed so as to surround the semiconductor layer 34. The charge storage layer 35b is formed so as to surround the tunnel insulating layer 35a. The block insulating layer 35c is formed so as to surround the charge storage layer 35b. Furthermore, the selection transistors ST1 and ST2 do not necessarily need to include the charge storage layer 35b and the block insulating layer 35c, and may be formed so as to include only the tunnel insulating layer (the gate insulating film) 35a.

The tunnel insulating layer 35a and the block insulating layer 35c are configured from, for example, silicon oxide (SiO₂). The charge storage layer 35b is configured from, for example, silicon nitride (SiN). The semiconductor layer 34, the tunnel insulating layer 35a, the charge storage layer 35b and a block insulating layer 35c form a MONOS transistor. The back gate conductive layer 31, the plurality of word line conductive layers 32 and the selection gate conductive layers 33a and 33b are respectively formed so as to surround the semiconductor layer 34 and the insulating film 35.

A source line layer 36 is formed in a planar shape which extends in the second direction D2. The source line layer 36 is formed so as to make contact with the upper surface of the pair of semiconductor pillars 34a adjacent to one another in the first direction D1. A bit line layer 37 is formed in a striped pattern extending in the first direction D1 at a predetermined pitch in the second direction D2. The bit line layer 37 is formed so as to make contact with the upper surface of the semiconductor pillar 34b. The source line layer 36 and the bit line layer 37 are configured from, for example, a metal such as tungsten (W). The source line layer 36 functions as the source line CELSRC illustrated in FIG. 2, and the bit line layer 37 functions as the bit line BL.

The configuration of the memory cell array 10 is disclosed in U.S. patent application Ser. No. 12/407,403 filed 19 Mar. 2009 and entitled “three dimensional stacked nonvolatile semiconductor memory”. In addition, the configuration thereof is disclosed in U.S. patent application Ser. No. 12/406,524 filed 18 Mar. 2009 and entitled “three dimensional stacked nonvolatile semiconductor memory”, in U.S. patent application Ser. No. 13/816,799 filed 22 Sep. 2011 and entitled “nonvolatile semiconductor memory device”, and in U.S. patent application Ser. No. 12/532,030 filed 23 Mar. 2009 and entitled “semiconductor memory and method for manufacturing the same”. The entire descriptions of these patent applications are incorporated by reference herein.

### 1-2. Configuration of Row Decoders 11

Next, the configuration of the row decoders 11 (11-1 and 11-2) is described. The row decoders 11-1 and 11-2 respectively include the transfer gates 15-1 and 15-2 and block decoders 43-1 and 43-2. In other words, in relation to one block, one block decoder is provided for each of the row decoders 11-1 and 11-2 (a total of two). The block decoder 43-1 of the row decoder 11-1 side, for example, executes the selection operations of the selection gate line SGS and the word lines WL0 to WLn/2−1. Meanwhile, the block decoder 43-2 of the row decoder 11-2 side, for example, executes the selection operations of the selection gate line SGD, the word lines WLn/2 to WLn−1 and the back gate line BG.

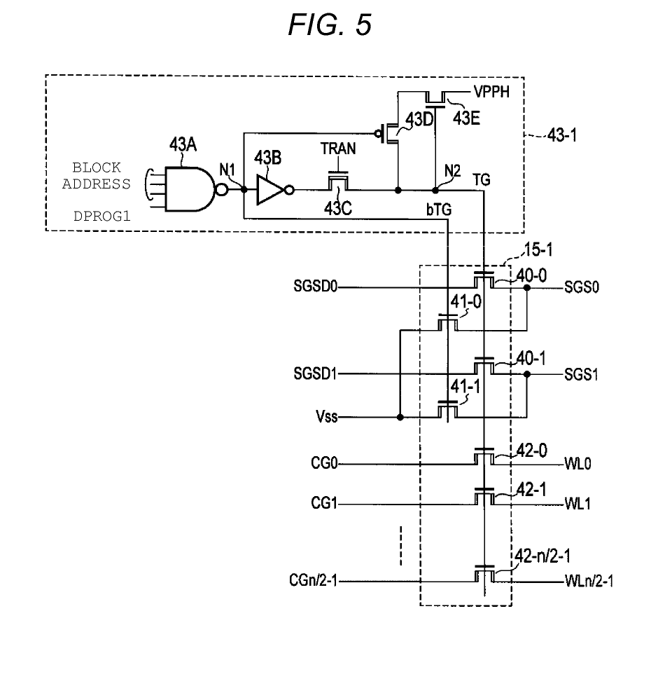

FIG. 5 is a circuit diagram of the transfer gate 15-1 and the block decoder 43-1. The block decoder 43-1 includes a NAND gate 43A, an inverter circuit 43B, high breakdown voltage n channel MOS transistors 43C and 43E, and a high breakdown voltage p channel MOS transistor 43D. In addition, the MOS transistor 43C is configured from a depression MOSFET.

The block address and the signal DPROG1 are supplied from the control circuit 14 to the input terminal of the NAND gate 43A. In the selected blocks, all of the bits in the block address are at a high level, and in the unselected blocks, at least one of the bits in the block address are at a low level. The signal DPROG1 is a signal which sets a portion of the word lines within the selected block to a floating state.

The signal DPROG1 is at a low level when the word lines WL0 to WLn/2−1 are set to a floating state, and is at a high level when a high voltage is applied to the word lines WL0 to WLn/2−1. The output terminal of the NAND gate 43A is connected to the input of the inverter circuit 43B and the gate of the MOS transistor 43D via a node N1. In addition, the output of the NAND gate 43A is supplied to the transfer gate 15-1 as the signal bTG.

The output terminal of the inverter circuit 43B is connected to an end of the current path of the MOS transistor 43C. The other end of the current path of the MOS transistor 43C is connected to a node N2 and a signal TRAN is supplied from the control circuit 14 to the gate. An end of the current path of the MOS transistor 43D is connected to an end of the current path of the MOS transistor 43E, and the other end is connected to the node N2. A high voltage VPPH is applied to the other end of the current path of the MOS transistor 43E and the gate is connected to the node N2.

In general, in a selected block, the block decoder 43-1 supplies a signal TG, which is of a high voltage at a voltage level possible to transfer, to the transfer gate 15-1, and in an unselected block, the block decoder 43-1 supplies the signal TG, which is of a voltage level at which the transfer gate 15-1 switches off, to the transfer gate. Specifically, the signal TRAN is fixed at 0V. In the unselected block, the node N1 is high level (the power supply voltage Vdd), and 0V is transferred to the node N2 via the depression n channel MOS transistor 43C. In addition, in the selected block, the node N1 is low level (0V), the output of the inverter circuit 43B is Vdd and the node N2≧Vdd. Therefore, the MOS transistor 43C is in an off state and the node N2 is set in the vicinity of the high voltage VPPH. Furthermore, by controlling the signal DPROG1, the signal TG which sets the word lines WL0 to WLn/2−1 to a floating state can also be supplied to the transfer gate 15-1 during writing.

Next, the configuration of the transfer gate 15-1 is described. Furthermore, in FIG. 5, the portions of the circuit for SGS0 and SGS1 are extracted and shown as the selection gate line SGS. The transfer gate 15-1 includes the high breakdown voltage n channel MOS transistors 40 (40-0 and 40-1), 41 (41-0 and 41-1) and 42 (42-0 to 42-n/2−1).

The MOS transistors 40 and 41 transfer a voltage to the selection gate line SGS. In each of the MOS transistors 40-0 and 40-1, an end of the current path is connected to the selection gate lines SGS0 and SGS1 of the corresponding block BLK, the other end is connected to the signal lines SGSD0 and SGSD1, and the signal TG is supplied to the gate. The signal lines SGSD0 and SGSD1 are connected to the driver circuit 19.

In each of the MOS transistors 41-0 and 41-1, an end of the current path is connected to the selection gate lines SGS0 and SGS1 of the corresponding block BLK, a voltage Vss (0V) is applied to the other end, and the signal bTG is supplied to the gate.

The MOS transistors 42 transfer voltages to the word lines WL. In each of the MOS transistors 42-0 to 42-n/2−1, an end of the current path is connected to each of the word lines WL0 to WLn/2−1 of the corresponding block BLK, the other end is connected to each of the signal lines CG0 to CGn/2−1, and the signal TG is supplied to the gate.

As the basic operation, in the transfer gate 15-1 corresponding to the selected block, the MOS transistors 40-0 and 40-1 are in an on state, and the MOS transistors 41-0 and 41-1 are in an off state. Accordingly, the selection gate lines SGS0 and SGS1 of the selected block are respectively connected to the signal lines SGSD0 and SGSD1. In addition, the MOS transistors 42-0 to 42-n/2−1 are in an on state, and the word lines WL0 to WLn/2−1 are connected to the signal lines CG0 to CGn/2−1.

Meanwhile, in the transfer gate 15-1 corresponding to the unselected block, the MOS transistors 40-0 and 40-1 are in an off state, and the MOS transistors 41-0 and 41-1 are in an on state. Accordingly, the voltage Vss is applied to the selection gate lines SGS0 and SGS1 of the unselected block. In addition, the MOS transistors 42-0 to 42-n/2−1 are in an on state, and the word lines WL0 to WLn/2−1 are electrically isolated from the signal lines CG0 to CGn/2−1.

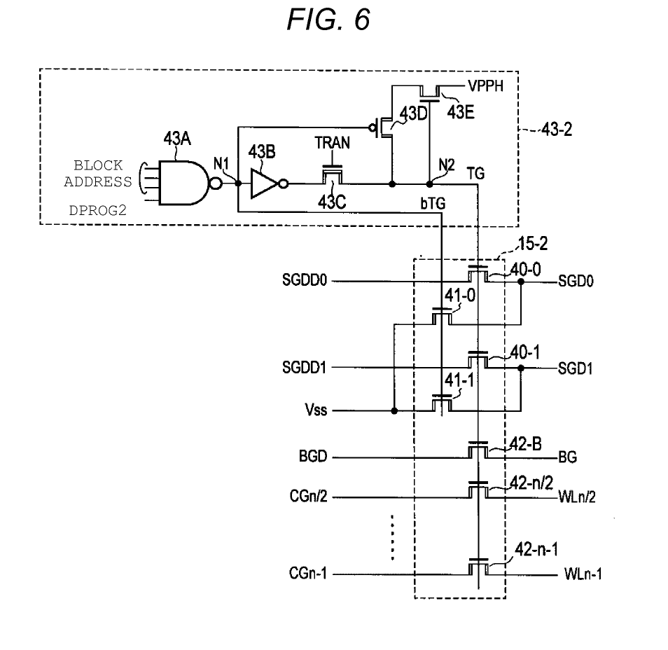

FIG. 6 is a circuit diagram of the transfer gate 15-2 and the block decoder 43-2. The circuit configuration of the block decoder 43-2 is the same as the block decoder 43-1 of FIG. 5. The block address and the signal DPROG2 are supplied from the control circuit 14 to the block decoder 43-2. Apart from a back gate line BG MOS transistor being added and the selection gate line SGS being changed to SGD, the transfer gate 15-2 has the same configuration as the transfer gate 15-1 of FIG. 5. The signal DPROG2 is a low level when the word lines WL0 to WLn/2−1 are set to a floating state, and is a high level when a high voltage is applied to the word lines WL0 to WLn/2−1. Furthermore, in the present embodiment, the signal DPROG2 is fixed at a high level.

In the MOS transistor 42-B, an end of the current path is connected to the back gate line BG of the corresponding block BLK, the other end is connected to the signal line BGD, and the signal TG is supplied to the gate. In relation to the selection gate line SGD, the operation and the circuit are similar to the selection gate line SGS described above, where the selection gate line SGS is replaced with a selection gate line SGD, and the signal line SGSD is replaced with a signal line SGDD. In relation to the word lines WLn/2−1 to WLn−1, the operation and the circuit are similar to the word lines WL0 to WLn/2−1, where the word lines WL0 to WLn/2−1 are replaced with the word lines WLn/2−1 to WLn−1, and the signal lines CG0 to CGn/2−1 are replaced with the signal lines CGn/2 to CGn−1.

### 1-3. Load Capacitance of Memory Cell Array 10

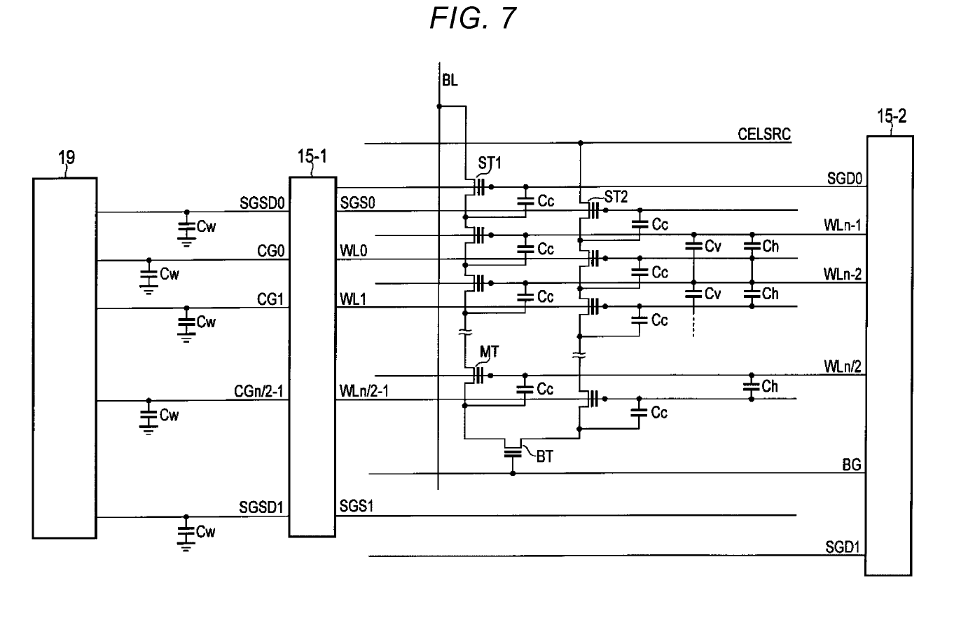

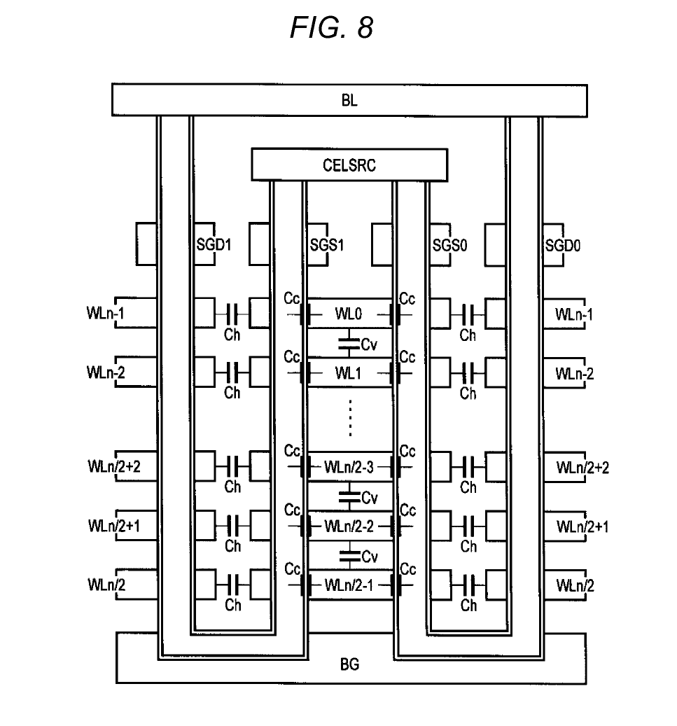

Next, the load capacitances of the memory cell array 10 and the peripheral circuits are described. FIG. 7 is a circuit diagram illustrating the load capacitance of the memory cell array 10. FIG. 8 is a cross-section diagram illustrating the load capacitances of the memory cell array 10. Furthermore, in FIG. 7, the load capacitances of the signal lines between the driver circuit 19 and the transfer gate 15-1 are extracted and shown.

The load capacitances Ch are the capacitances between the word lines contained in the same layer. The load capacitances Cv are the capacitances between the word lines adjoined in the vertical direction. The load capacitances Cc are the capacitances between the word lines WL and the channels.

Furthermore, there are also the load capacitances Cw of the wiring (including the signal lines SGDD, SGSD and CG) connecting the driver circuit 19 and the transfer gates 15-1 and 15-2. The load capacitances Cw differ for each signal, however, the same symbol is used here. In addition, there are capacitances in relation to various signals, however, for simplicity, they are all represented as capacitances to ground.

As shown in FIG. 7 and FIG. 8, the load capacitance is great in three-dimensional stacked NAND type flash memory, in comparison with planar NAND type flash memory, for example. Accordingly, the word lines adjacent to one another in the vertical direction and the horizontal direction greatly receive the influence of the voltage of one another, and the signal lines SGDD, SGSD and CG also greatly receive the influence of the voltage of one another.

### 2. Operations

Next, the operations of the semiconductor memory device 1 configured as described above are described. In the present embodiment, when writing data to the memory cell transistors closer to the bit line side than the back gate transistor BT, the word lines closer to the source line side than the back gate transistor BT are set to a floating state. In the three-dimensional stacked NAND type flash memory, since the coupling capacitance between the word lines is great, the channels of the source line side are boosted by setting the word lines closer to the bit line side than the back gate transistor BT to a high voltage, thereby also raising the word lines of the source line side via coupling. Accordingly, in the latter half of the write operation, there is no longer a need to apply a high voltage to half of the word lines of the source line side, and the power consumption can be suppressed.

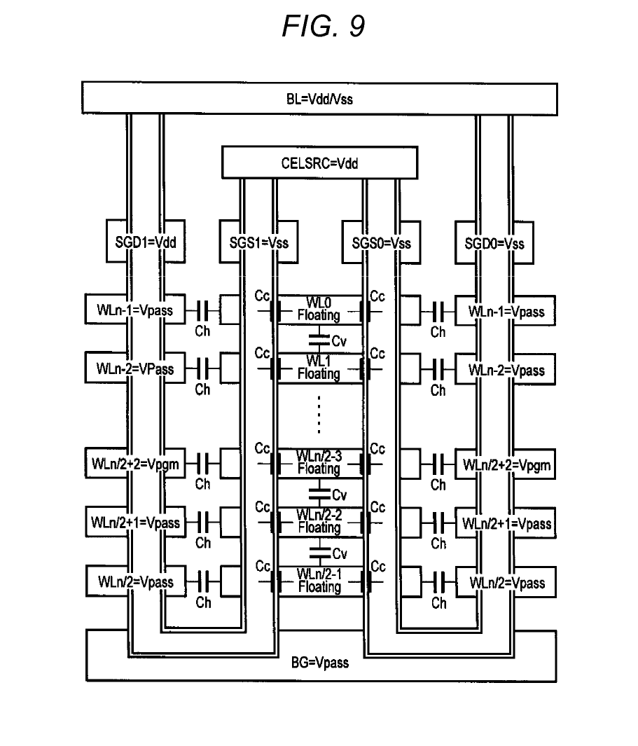

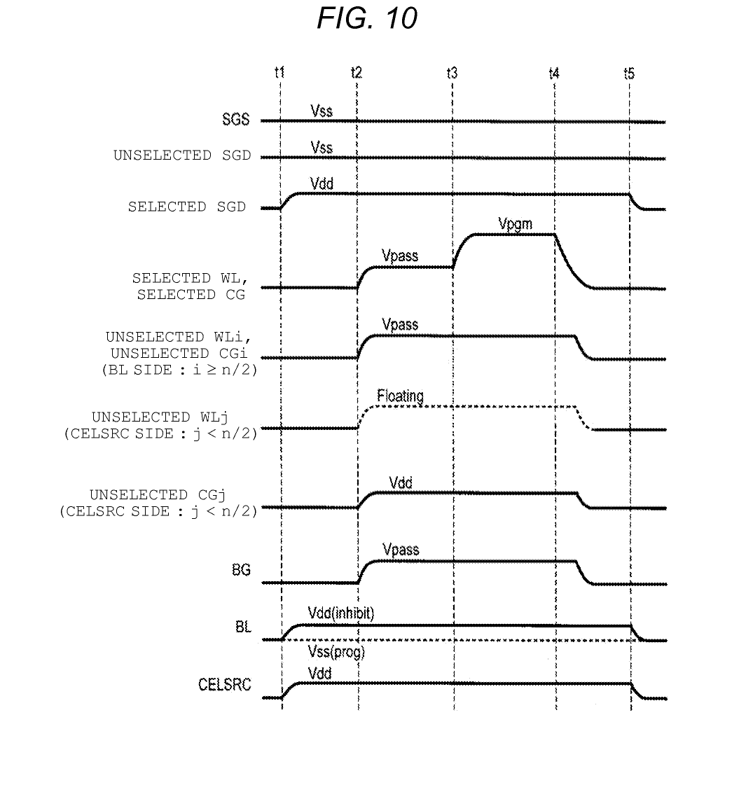

FIG. 9 is a view illustrating the voltage relationships during the write operation. FIG. 10 is a timing chart of the write operation.

In the write operation, for example, the word lines are programmed in ascending order, in other words, in order from the word line WL0 closest to the source line side. The writing to the word lines WL0 to WLn/2−1 closer to the source line side than the back gate line BG is the same as in a general write operation.

The write operation to the word lines WLn/2 to WLn−1 of the bit line side is described below. First, at the time t1, one of the voltage Vss and the power supply voltage Vdd is applied to the bit line BL, corresponding to whether the bit line BL is writable or write-protected. Specifically, when writing data to the selected memory cells of the NAND string connected to a certain bit line BL, in other words, when raising the threshold voltage by injecting a charge into the charge storage layer of the selected memory cell, the voltage Vss is applied to the bit line BL. In contrast, when the selected memory cells of the NAND string connected to a certain bit line BL are write-protected, in other words, when maintaining the threshold voltage without injecting a charge into the charge storage layer of the selected memory cell, the power supply voltage Vdd is applied to the bit line BL.

In addition, the voltage Vss is applied to all of the selection gate lines SGS within the selected block, and the power supply voltage Vdd is applied to the source line CELSRC. Accordingly, the selection transistor ST2 is cut off. Furthermore, the power supply voltage Vdd is applied to the selection gate line SGD (SGD1 of FIG. 9, selected SGD of FIG. 10) of the selected string group GP. Accordingly, in the NAND string to which data is written, the selection transistor ST1 is on, and the bit line voltage (the voltage Vss) is transferred to the channel. Meanwhile, in the NAND string which is write-protected, the gate and the source of the selection transistor ST1 are the same voltage, and the selection transistor ST1 is cut off. Furthermore, the voltage Vss is applied to the selection gate line SGD (SGDO of FIG. 9, unselected SGD of FIG. 10) of the unselected string group GP.

Next, at the time t2, the word lines WL0 to WLn/2−1 closer to the source line side than the back gate line BG are set to a floating state. Specifically, the control circuit 14 supplies the low level signal DPROG1 to the block decoder 43-1 contained in the row decoder 11-1. Accordingly, the signal TG of a low level (for example 0V) is supplied to the transfer gate 15-1. In addition, the driver circuit 19 applies the power supply voltage Vdd to the signal lines CG0 to CGn/2−1. As a result, the MOS transistors 42 connected to the word lines WL0 to WLn/2−1 are cut off, and the word lines WL0 to WLn/2−1 enter a floating state.

The pass voltage Vpass (for example, 10V) is applied to the word lines WLn/2 to WLn−1 closer to the bit line side than the back gate line BG, and to the back gate line BG. Specifically, the control circuit 14 supplies the high level signal DPROG2 to the block decoder 43-2 contained in the row decoder 11-2. Accordingly, the signal TG of a high voltage at a level possible to transfer is supplied to the transfer gate 15-2. In addition, the driver circuit 19 applies the pass voltage Vpass to the signal lines CGn/2 to CGn−1, and the pass voltage Vpass of the signal lines CGn/2 to CGn−1 is transferred to the respective word lines WLn/2 to WLn−1. The pass voltage Vpass is a high voltage which sets the memory cell transistors to an on state regardless of the maintained data.

Next, at the time t3, the writing voltage Vpgm (for example, 20V) is applied to the selected word lines (in the example of FIG. 9, the word line WLn/2+2) via the corresponding signal lines CG. The writing voltage Vpgm is a high voltage which injects a charge into the charge storage layer.

Here, since the word lines WL0 to WLn/2−1 of the source line side are substantially surrounded by the word lines WLn/2 to WLn−1 of the bit line side and the back gate line BG, the voltages of the word lines WL0 to WLn/2−1 rise due to coupling. Since the channels also enter a floating state when a maximum number of the memory cell transistors contained in the selected page is write-protected, the capacitances between the word lines and the channels are practically unobservable, and the voltages of the word lines WL0 to WLn/2−1 of the source line side rise to the vicinity of the pass voltage Vpass. As a result, the channels are also boosted to an appropriate level, and the write-protected state is realized.

Furthermore, since the channels are of the same voltages as the bit lines when data is written to a maximum number of the memory cell transistors contained in the selected page (the threshold voltage is raised), the capacitances between the word lines and the channels are visible, and the voltages of the word lines of the source line side barely rise. However, there is no problem, since the channel voltage needs only to be the same voltage as the bit line (the voltage Vss). For example, when the threshold voltage of a certain memory cell transistor of the source line side is high and the word line voltage does not rise to an appropriate level, the channels are cut off at the position of the memory cell transistor and a portion of the channel closer to the source line side is boosted. However, there is no problem in the writing of the selected memory cell transistor even when the portion of the channel is boosted.

As a result of the above, in the selected string group GP, the selection transistor ST1 is set to an on state in the NAND string in which 0V is applied to the bit line BL. Therefore, 0V is transferred to the channel of the selected memory cell transistor and a charge is injected into the charge storage layer. On the other hand, the selection transistor ST1 is cut off in the NAND string in which Vdd is applied to the bit line BL. As a result, the channels of the NAND string enter a floating state, and the channel voltages rise due to the coupling with the word lines. As a result, a charge is not injected into the charge storage layer of the memory cell transistor and data is not written. In the unselected string group, the selection transistors ST1 and ST2 are in an off state. Accordingly, data is also not written to the unselected string group.

### 3. Effects

In NAND type flash memory, the parasitic capacitance of the word lines has a tendency to be great since the word lines are shared by a plurality of adjacent memory strings, and the periphery of each of the word lines is surrounded by other word lines and the like due to stacked structure. As a result, the power consumption increases because the RC delay of the word line increases, the writing performance decreases and there is a need to charge a great capacity at a high voltage created using a booster circuit.

In contrast, in the first embodiment, during the latter half of the write operation, in other words, when writing data to the memory cell transistors closer to the bit line side than the back gate transistor BT, the word lines of the source line side are set to a floating state. The word lines which are in a floating state rise to the vicinity of the pass voltage Vpass due to coupling with the adjacent word lines, and furthermore, the channels are also boosted to a suitable level for the write protection operation due to coupling with the word lines. Accordingly, in the latter half of the writing, since there is no longer a need to apply the pass voltage Vpass to half of the word lines, the power consumption can be reduced by the amount it takes to charge the corresponding wiring capacity. In particular, the power consumption can be reduced by the amount it takes to charge the load capacitances Cw of the signal lines CG which transfer voltages to the word lines WL of the source line side.

### Second Embodiment

In the second embodiment, the word lines closer to the source line side than the back gate transistor are set to a floating state, and the channels of the bit line side are cut off in part. Furthermore, the boost efficiency is improved by limiting the channel regions boosted during writing.

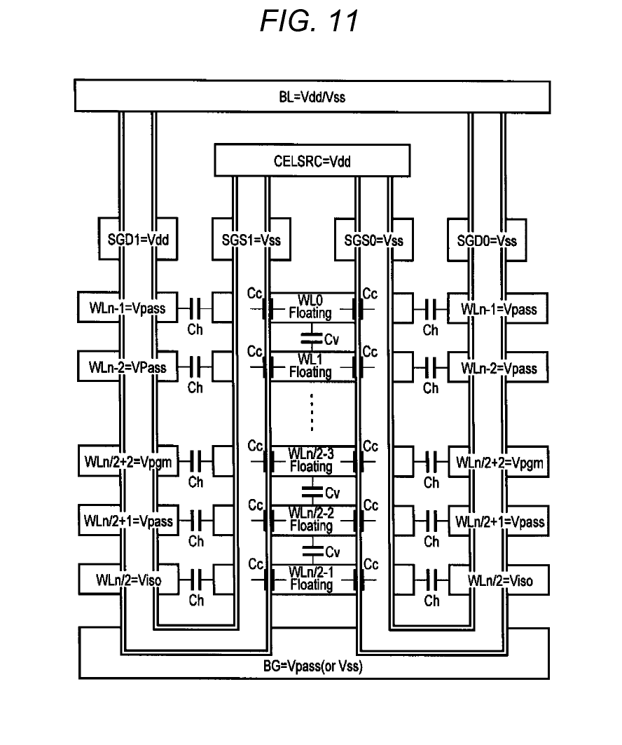

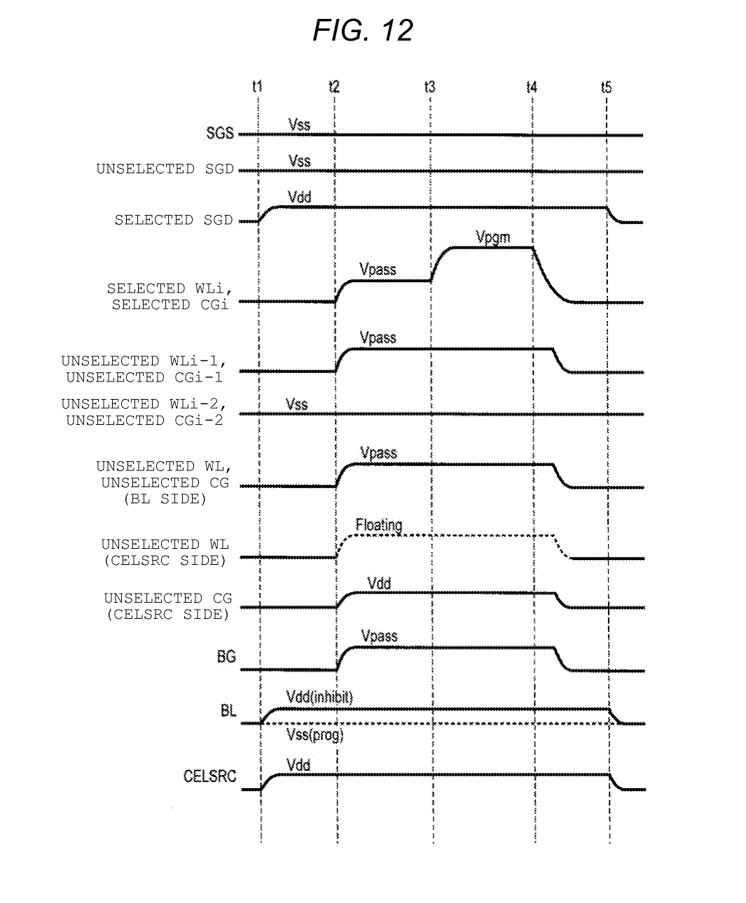

FIG. 11 is a view illustrating the voltage relationships in a write operation according to the second embodiment. FIG. 12 is a timing chart of the write operation.

The write operation of the second embodiment is applied to the word line WLn/2+2 onward. The word line targeted for writing is the selected word line WLi, where “i≧n/2+2”. In the example of FIG. 11, the selected word line WLi=WLn/2+2.

First, at the time t1, the cut off voltage Viso (for example, the voltage Vss) is applied to the unselected word line WLi−2. In the example of FIG. 11, the unselected word line WLi−2=WLn/2. Accordingly, the memory cell transistors connected to the unselected word line WLi−2 cut off the channels of the NAND string.

Next, at the time t2, the pass voltage Vpass is applied to the unselected word lines other than the word lines WLi and WLi−2 among the word lines WLn/2 to WLn−1 of the bit line side. The voltages of the word lines WLn/2 to WLn−1 are transferred by the driver circuit 19 via the signal lines CGn/2 to CGn−1. In addition, the pass voltage Vpass is applied to the back gate line BG. Furthermore, the word lines WL0 to WLn/2−1 of the source line side are set to a floating state. Accordingly, in the write-protected NAND string, the channel voltages closer to the bit line side than the unselected word line WLi−2 are boosted. Furthermore, the voltage Vss may be applied to the back gate lines BG.

Next, at the time t3, the writing voltage Vpgm (for example, 20V) is applied to the selected word line WLi via the corresponding signal line CGi. At this time, the write-protected state is realized in the write-protected memory cell transistor.

Furthermore, as described above, since the word lines WL0 to WLn/2−1 of the source line side may not be set to a floating state until the writing of the word line WLn/2+1, the write operation of the second embodiment is applied to the word line WLn/2+2 onward.

In the first embodiment, since the channels of the NAND string remain connected, if the boost efficiency of the word lines set to a floating state is poor, the channel voltage does not rise much, and the write-protection operation of the selected cells may be affected. In contrast, in the second embodiment, the channels of the NAND string can be cut off in part. Accordingly, the channel voltages of the selected cells are sufficiently boosted to perform the write-protection operation. In addition, the word lines WL0 to WLn/2−1 of the source line side rise to the vicinity of the pass voltage Vpass by coupling, and the channels are also boosted to an appropriate level. As a result, the cut off properties of the channel according to the word line WLi−2 are improved.

In addition, since the word lines WL0 to WLn/2−1 of the source line side are set to a floating state during writing of the word lines WLn/2 to WLn−1 of the bit line side, the power consumption can be reduced.

### Third Embodiment

In the third embodiment, the word line closer to the source line side than the back gate transistor is set to a floating state, and the channel of the NAND string is cut off at the back gate transistor. Furthermore, the boost efficiency is improved by limiting the channel regions boosted during writing.

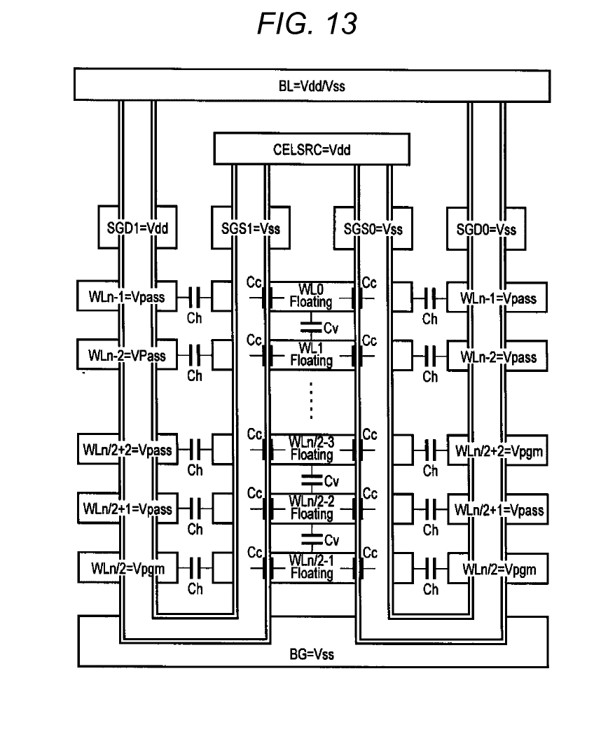

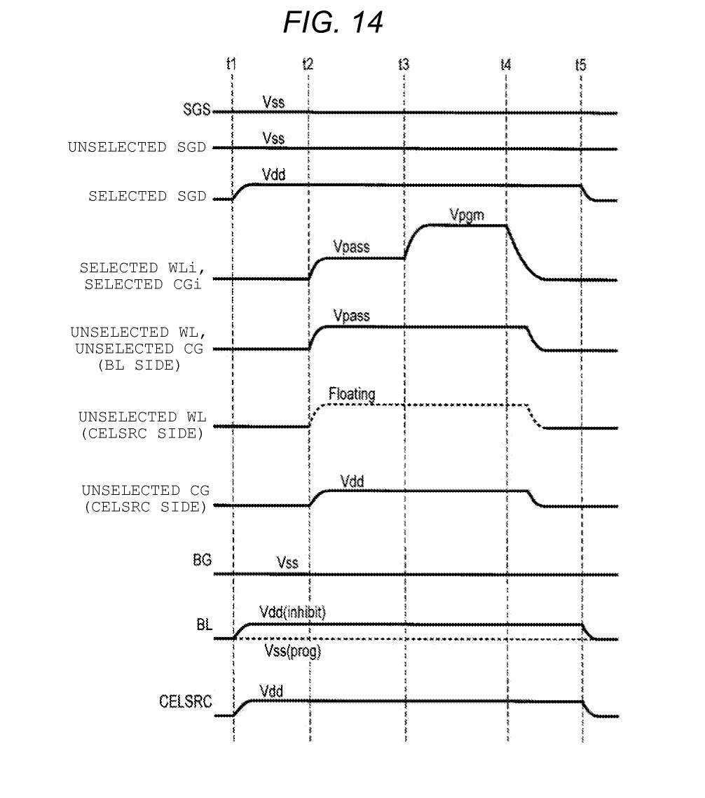

FIG. 13 is a view illustrating the voltage relationships in a write operation according to the third embodiment. FIG. 14 is a timing chart of the write operation.

The word line targeted for writing is the selected word line WLi, where “i≧n/2”. In the example of FIG. 13, the selected word line WLi=WLn/2.

First, at the time t1, the voltage Vss is applied to the back gate line BG. Accordingly, the back gate transistors BT cut off the channels of the NAND string. The subsequent write operations are the same as in the first embodiment.

According to the third embodiment, during writing of the word lines WLn/2 to WLn−1 of the bit line side, the channels of the NAND string can be cut off at the position of the back gate transistor BT. Accordingly, the channel voltages of the selected cells are sufficiently boosted to perform the write-protection operation.

The self-boosting method of the second embodiment may only be applied to the write operations from memory cell transistors which are slightly distanced from the back gate transistor to the bit line side (for example, the third memory cell transistor from the back gate). However, the self-boosting method of the third embodiment can be applied from the memory cell transistor adjacent to the bit line side from the back gate transistor.

In addition, since the word lines WL0 to WLn/2−1 of the source line side are set to a floating state during writing of the word lines WLn/2 to WLn−1 of the bit line side, the power consumption can be reduced.

In each of the above embodiments, the plurality of word lines connected to a NAND string are managed by dividing the word lines into a first group of the source line side and a second group of the bit line side, with the back gate line as the boundary, and the first group of the source line side is set to a floating state. However, the embodiments are not limited thereto, and the plurality of word lines connected to a NAND string may also be managed by dividing the word lines into three or more groups. For example, the word lines closer to the source line side than the back gate transistor may be further divided into two groups, the word lines of the bit line side may be further divided into two groups, and the plurality of word lines connected to a NAND string may be divided into a total of four groups. Furthermore, the write operations of each of the above embodiments can be applied from the half of the word lines of the source line side (the word line WLn/4). Furthermore, in such an example, the transfer gates also need to be divided corresponding to the number of groups.

The configuration of the NAND string is not limited to a U-shape, and may also be an I-shape. In other words, a source line is provided on a substrate, a source side selection gate is provided thereon, word lines are provided in a plurality of layers thereon, and a drain side selection gate is provided between the word line and the bit line of the uppermost layer. The writing methods of each of the embodiments described above can also be applied to memory which includes the NAND string.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a memory string including first and second selection transistors, a back gate transistor, a first group of memory cell transistors connected in series between the first selection transistor and the back gate transistor, and a second group of memory cell transistors connected in series between the second selection transistor and the back gate transistor;
a bit line connected to the first selection transistor;
a source line connected to the second selection transistor;
a plurality of first word lines respectively connected to gates of the memory cell transistors in the first group;
a plurality of second word lines respectively connected to gates of the memory cell transistors in the second group;
a back gate line connected to a gate of the back gate transistor;
a plurality of first transfer transistors respectively connected to the first word lines;
a plurality of second transfer transistors respectively connected to the second word lines; and
a control unit configured to apply a first control voltage to gates of the first transfer transistors and a second control voltage lower than the first control voltage to gates of the second transfer transistors when data is being written to memory cell transistors in the first group.

2. The semiconductor memory device according to claim 1, wherein the control unit is configured to cause a first voltage to be applied to a selected word line connected to selected memory cell transistors targeted for writing, and a second voltage, which is lower than the first voltage, to be applied to an unselected word line connected to unselected memory cell transistors.

3. The semiconductor memory device according to claim 1, wherein the control unit is configured to cause a first voltage to be applied to a selected word line connected to selected memory cell transistors targeted for writing, a second voltage, which cuts off channels, to a first unselected word line between the selected word line and the back gate line, and a third voltage, which is lower than the first voltage, to a second unselected word line that is different from the first unselected word line.

4. The semiconductor memory device according to claim 3, wherein the second unselected word line is between the selected word line and the first unselected word line.

5. The semiconductor memory device according to claim 1, wherein the second control voltage causes power supplied to the second word lines to be cut off.

6. The semiconductor memory device according to claim 1, further comprising a third transfer transistor connected to the back gate line, wherein the control unit is configured to apply a third control voltage to a gate of the third transfer transistor to switch off the back gate transistor when data is being written to memory cell transistors in the first group.

7. A semiconductor memory device, comprising:
a memory string in which a first selection transistor, a first memory cell group, a back gate transistor, a second memory cell group and a second selection transistor are connected in series, and each of the first and the second memory cell groups is stacked above a semiconductor substrate and includes a plurality of memory cell transistors connected in series;
a bit line connected to the first selection transistor;
a source line connected to the second selection transistor;
first and second selection gate lines respectively connected to gates of the first and the second selection transistors;
a plurality of word lines respectively connected to gates of the memory cell transistors;
a back gate line connected to a gate of the back gate transistor;
a plurality of transfer gates respectively connected to word lines of the second memory cell group; and
a control unit configured to control a write operation of the memory string and the transfer gates, the control unit being configured to apply a first control voltage to the transfer gates when data is being written to the second memory cell group and a second control voltage to the transfer gates when data is being written to the first memory cell group, the first control voltage being higher than the second control voltage.

8. The semiconductor memory device according to claim 7,
wherein the control unit is configured to cause a first voltage to be applied to a selected word line connected to selected cells targeted for writing, and a second voltage, which is lower than the first voltage, to be applied to an unselected word line connected to unselected cells.

9. The semiconductor memory device according to claim 7,
wherein the control unit is configured to cause a first voltage to be applied to a selected word line connected to selected cells targeted for writing, a second voltage, which cuts off channels, to a first unselected word line between the selected word line and the back gate line, and a third voltage, which is lower than the first voltage, to a second unselected word line that is different from the first unselected word line.

10. The semiconductor memory device according to claim 9, wherein the second unselected word line is between the selected word line and the first unselected word line.

11. The semiconductor memory device according to claim 7, wherein the second control voltage causes power supplied to the word lines of the second memory cell group to be cut off.

12. The semiconductor memory device according to claim 7, further comprising a third transfer transistor connected to the back gate line, wherein the control unit is configured to apply a third control voltage to a gate of the third transfer transistor to switch off the back gate transistor when data is being written to the first memory cell group.

13. A method of performing a write operation in a semiconductor memory device including a memory string including first and second selection transistors, a back gate transistor, a first group of memory cell transistors connected in series between the first selection transistor and the back gate transistor, and a second group of memory cell transistors connected in series between the second selection transistor and the back gate transistor, a bit line connected to the first selection transistor, a source line connected to the second selection transistor, a plurality of first word lines respectively connected to gates of the memory cell transistors in the first group, a plurality of second word lines respectively connected to gates of the memory cell transistors in the second group, a back gate line connected to a gate of the back gate transistor, a plurality of first transfer transistors respectively connected to the first word lines, and a plurality of second transfer transistors respectively connected to the second word lines, said method comprising:
writing data to memory cell transistors in the first group; and
while writing said data, applying a first control voltage to gates of the first transfer transistors and a second control voltage lower than the first control voltage to gates of the second transfer transistors.

14. The method of claim 13, further comprising:
applying a first voltage to a selected word line connected to selected memory cell transistors targeted for writing; and
applying a second voltage, which is lower than the first voltage, to an unselected word line connected to unselected memory cell transistors.

15. The method of claim 13, further comprising:
applying a first voltage to a selected word line connected to selected memory cell transistors targeted for writing; and
applying a second voltage, which cuts off channels, to a first unselected word line between the selected word line and the back gate line; and
applying a third voltage, which is lower than the first voltage, to a second unselected word line that is different from the first unselected word line,
wherein the second unselected word line is between the selected word line and the first unselected word line.

16. The method of claim 13, further comprising:
cutting off power supplied to the second word lines.

17. The method of claim 13, further comprising:
while writing said data, switching off the back gate transistor.
